(19) United States
(12) Patent Application Publication
(10) Pub. No.: US 2012/0146467 A1
(43) Pub. Date: Jun. 14, 2012

(54) HOUSING OF ELECTRONIC DEVICE AND METHOD FOR MAKING THE SAME

(75) Inventors: YONG-GANG ZHU, Shenzhen City (CN); XIN-WU GUAN, Shenzhen City (CN)

(73) Assignees: FIH (Hong Kong) Limited, Kowloon (HK); SHENZHEN FUTAIHONG PRECISION INDUSTRY CO., LTD., ShenZhen City (CN)

(21) Appl. No.: 13/090,352

(22) Filed: Apr. 20, 2011

(30) Foreign Application Priority Data
Dec. 10, 2010 (CN) 201010582646.7

(51) Int. Cl. H05K 5/02; B05D 3/12

(52) U.S. Cl. 312/223.1; 427/327

(57) ABSTRACT

Housing of electronic device includes a metal base, a ceramic layer forming on the metal base, and at least one pattern formed on the surface of the ceramic layer. The disclosure also described a method to make the housing.

### CROSS-REFERENCE TO RELATED APPLICATIONS

This application is related to co-pending U.S. patent application Ser. No. (Attorney Docket No. US37448) entitled “HOUSING OF ELECTRONIC DEVICE AND METHOD FOR MAKING THE SAME”. Such application has the same assignee as the present application. The above-identified application is incorporated herein by reference.

### BACKGROUND

1. Technical Field

The present disclosure relates to housings of electronic devices and a method for making the same.

2. Description of the Related Art

At least one pattern on many housings of electronic devices are formed by printing or application of transfers or paint that are not strongly bonded to the surface of the housing Therefore, the materials used can easily be worn or scraped off.

Therefore, there is room for improvement within the art.

### BRIEF DESCRIPTION OF THE DRAWINGS

Many aspects of the present housing of electronic device and method for making the same can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a front isometric view of a housing of an electronic device according to an exemplary embodiment.

FIG. 2 is a sectional schematic view of the housing shown in FIG. 1 along a line II-II.

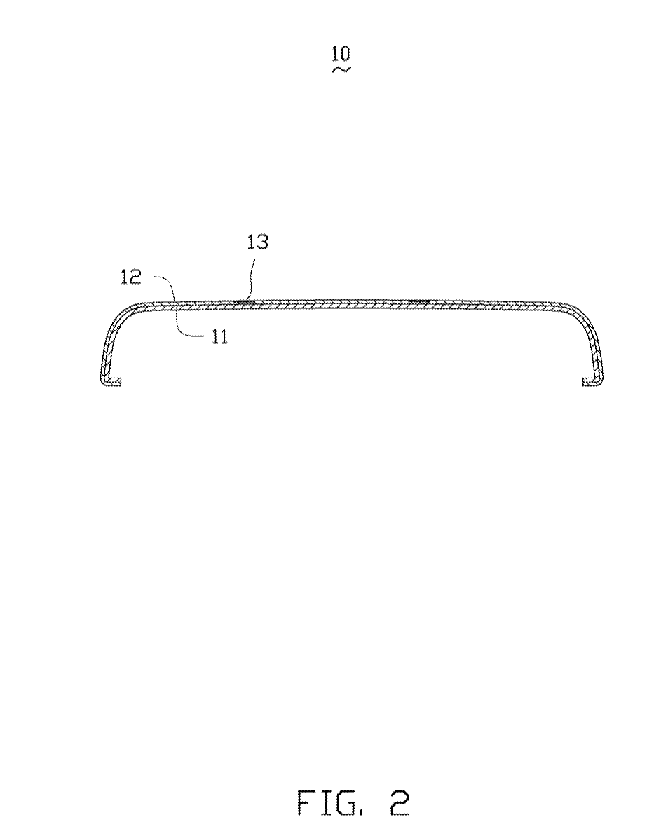

FIG. 3 is a flow chart to fabricate the housing shown in FIG. 1.

### DETAILED DESCRIPTION

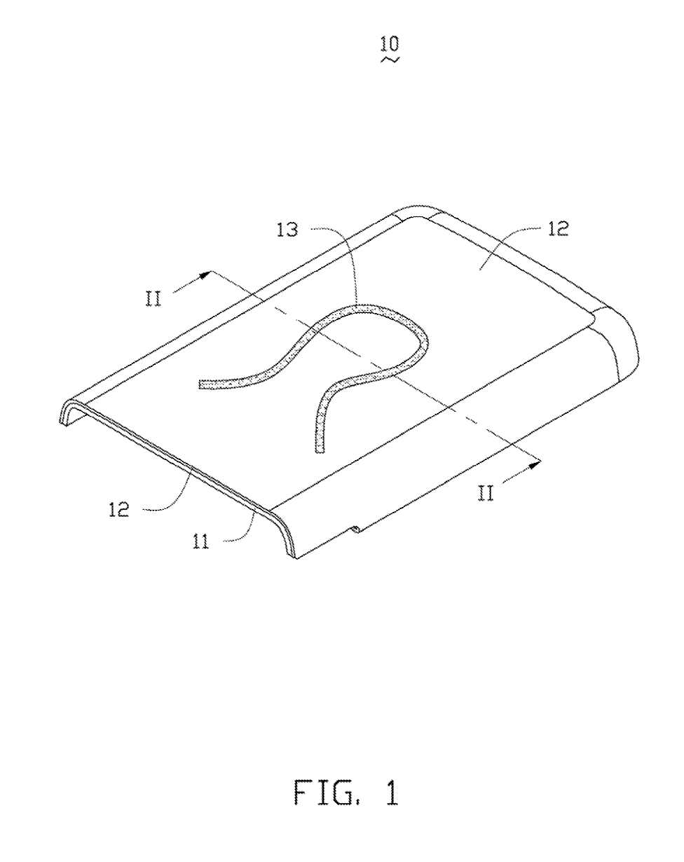

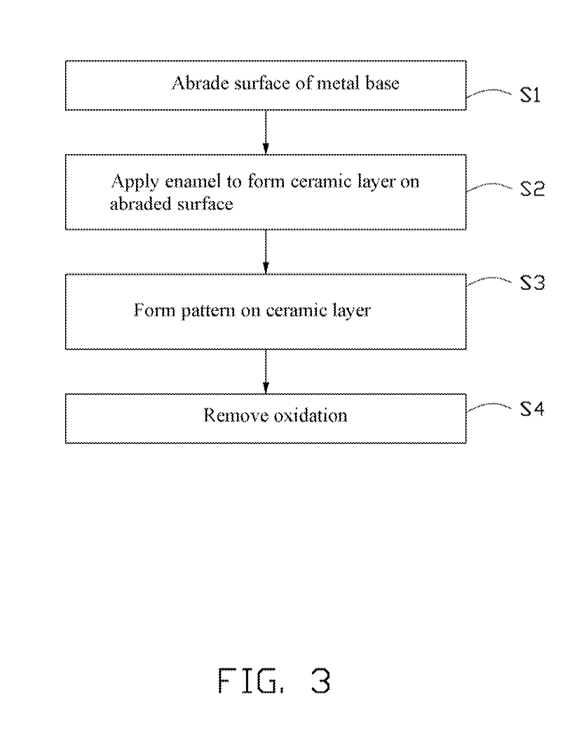

FIGS. 1 and 3 show an exemplary embodiment of a housing 100 of an electronic device such as a mobile phone. The housing 100 includes a metal base 11 and a ceramic layer 12 integrally formed on the external surface of the base 11. The base 11 can be stainless steel. A thickness of the base 11 can be 0.5 mm (millimeter) or more, and is about 0.5 mm in this exemplary embodiment. A thickness of the ceramic layer 12 is in a range of 0.18 mm-0.4 mm, and is 0.2 mm in this exemplary embodiment. The thicknesses of the base 11 and the ceramic layer 12 are independent of each other. The ceramic layer 12 has at least one pattern 13 formed on the external surface.

FIG. 3 shows a process to fabricate the housing 100, the process includes following steps:

Step 1: A metal base 11 is provided and processed to abrade a surface thereof. Before abrading the surface, the base 11 is cleaned and dried. A conventional cleaning solution such as oxalic acid, or sodium hydroxide (NaOH) may be used to clean the surface of the base 11. Then, the surface is abraded by, for example, sand-blasting. The blasting material used may be comprised of emery, chromium iron alloy, copper ore, quartz sand, or ceramic base sand.

Step 2: The base 11 is coated with enamel after abrading to form the ceramic layer 12 on the surface. The enamel may be applied in two steps: glazing then baking. During glazing, the enamel glaze may comprise inorganic silicate to form the ceramic layer 12 and is electrically conductive. The glaze is evenly arranged on the surface of the base 11, then the base 11 is placed in an electrical field, causing the base 11 and the glaze to be oppositely charged and thereby form a bond. The thickness of the glaze can be adjusted by adjusting the intensity of the electrical field. During baking, the base 11 is placed into an oven and heated, and the glaze is melted evenly to form the ceramic layer 12. Due to abrasion of the surface, the ceramic layer 12 will firmly attach to the surface of the base 11. Then, the oven is allowed to cool and then the base 11 is taken out from the oven.

Step 3: The base 11 having the ceramic layer 12 is processed to form at least one pattern 13 on the ceramic layer 12. The processing includes following steps: a carrier film is provided that has been treated with paint corresponding to the at least one pattern 13. The carrier film is attached on the base 11, with the paint pressed against the ceramic layer 12. The base 11 is placed into an oven and heated, transferring the paint to the ceramic layer 12 to form the at least one pattern 13. The remainder of the carrier film evaporates. The paint can include inorganic silicate.

Step 4: During the above steps, an oxidation layer may form on the internal surfaces of the base 11. In this step any oxidized surfaces may be sand blasted as above to remove the oxidized layer.

It is to be understood that even though numerous characteristics and advantages of the present embodiments have been set forth in the foregoing description, together with details of assemblies and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

1. A housing of electronic device, comprising:
a metal base;
a ceramic layer formed on the metal base; and
at least one pattern formed on the surface of the ceramic layer.

2. The housing of electronic device as claimed in claim 1, wherein a thickness of the base is at least 0.5 mm (millimeter).

3. The housing of electronic device as claimed in claim 1, wherein a thickness of the ceramic layer is in a range of 0.18 mm-0.4 mm.

4. A method for making a housing of electronic device, comprising:
providing a metal base;
abrading a surface of the metal base;
forming a ceramic layer on the abraded surface;
forming at least one pattern on the ceramic layer.

5. The method for making a housing of electronic device as claimed in claim 4, further comprising cleaning and drying the metal base of greases on the surface thereof before abrading the surface.

6. The method for making a housing of electronic device as claimed in claim 4, wherein forming a ceramic layer on the abraded surface further comprises glazing an enamel glaze on the abraded surface and baking the enamel glaze.

7. The method for making a housing of electronic device as claimed in claim 6, wherein: during glazing, an enamel glaze is evenly arranged on the surface of the metal base, the metal base is placed into an electrical field, causing the base and the enamel glaze to be oppositely charged and thereby bonding together.

8. The method for making a housing of electronic device as claimed in claim 6, wherein: during baking, the enamel glaze is melted evenly over the metal base to form the ceramic layer.

9. The method for making a housing of electronic device as claimed in claim 7, wherein: the enamel glaze is an inorganic silicate to form the ceramic layer.

10. The method for making a housing of electronic device as claimed in claim 7, wherein: forming at least one pattern on the ceramic layer includes providing a carrier film treated with paint, attaching the carrier film on the ceramic layer, and heating the base, thereby transferring the paint to the ceramic layer to form the at least one pattern.

11. The method for making a housing of electronic device as claimed in claim 7, further comprising removing any oxidized layers formed on the internal surface of the base opposite to the ceramic layer.
